(19) United States
(12) Patent Application Publication
(10) Pub. No.: US 2015/0296622 A1
(43) Pub. Date: Oct. 15, 2015

(54) Flexible Printed Circuit With Semiconductor Strain Gauge

(71) Applicant: Apple Inc., Cupertino, CA (US)

(72) Inventors: Tongbi T. Jiang, Santa Clara, CA (US); Matthew E. Last, Santa Clara, CA (US); Henry H. Yang, Los Gatos, CA (US)

(73) Assignee: Apple Inc., Cupertino, CA (US)

(21) Appl. No.: 14/250,942

(22) Filed: Apr. 11, 2014

(51) Int. Cl. H05K 1/18; H05K 1/11; H05K 1/02; G01B 7/16

(52) U.S. Cl. CPC H05K 1/181; G01B 7/16; H05K 1/115; H05K 1/028; H05K 2201/0154; H05K 2201/10151

(57) ABSTRACT

A semiconductor strain gauge may be incorporated into a flexible printed circuit. The semiconductor strain gauge may be mounted in an opening in the flexible printed circuit. Electrical connections such as wire bonds may couple the semiconductor strain gauge to metal traces on a flexible printed circuit substrate in the flexible printed circuit. A flexible printed circuit opening may be filled with an encapsulant that encapsulates a semiconductor strain gauge. Vias may be formed through the encapsulant to contact the semiconductor strain gauge. Metal traces that run across the surface of the substrate and the encapsulant may contact the vias to form paths to the semiconductor strain gauge. A semiconductor strain gauge may be mounted on a substrate and covered with dielectric. Metal traces in a redistribution layer in the dielectric may overlap the semiconductor strain gauge and make contact to the semiconductor strain gauge.

### BACKGROUND

This relates generally to electronic devices and, more particularly, to electronic devices with components such as strain gauges.

Electronic devices often include sensors. Sensors allow information to be gathered on the operating environment of an electronic device. Sensors can also be used to gather user input.

In some situations, buttons may be used to gather user input. Buttons may be based on mechanical components such as dome switches.

Mechanical button components may be subject to wear during use and may be bulkier than desired. Mechanical button components may also be challenging to integrate with other components.

It would therefore be desirable to be able to provide improved sensors for electronic devices such as strain gauge sensors that can be used in implementing buttons.

### SUMMARY

An electronic device may be provided with a flexible printed circuit. A semiconductor strain gauge may be incorporated into flexible printed circuit. A component such as a fingerprint sensor may be mounted to the flexible printed circuit over the semiconductor strain gauge. The semiconductor strain gauge may be mounted to a display cover layer to serve as a strain-gauge-based button.

The semiconductor strain gauge may be mounted in an opening in the flexible printed circuit. Electrical connections such as wire bonds may couple the semiconductor strain gauge to metal traces on a flexible printed circuit substrate in the flexible printed circuit. The fingerprint sensor may also be coupled to metal traces on the flexible printed circuit using wire bonds.

The flexible printed circuit opening may be filled with an encapsulant that encapsulates the semiconductor strain gauge. Vias may be formed through the encapsulant to contact the semiconductor strain gauge. Metal traces that run across the surface of the substrate and the surface of the encapsulant may contact the vias. The metal traces and the vias may form signal paths to the semiconductor strain gauge.

The semiconductor strain gauge may be mounted on the surface of a substrate. A dielectric such as polymer may cover the semiconductor strain gauge and the surface of the substrate. Metal traces in the dielectric may form a redistribution layer in the dielectric. The metal traces of the redistribution layer may overlap the semiconductor strain gauge and make contact to the semiconductor strain gauge.

### BRIEF DESCRIPTION OF THE DRAWINGS

FIG. 1 is a perspective view of an illustrative electronic device such as a laptop computer in accordance with an embodiment.

FIG. 2 is a perspective view of an illustrative electronic device such as a handheld electronic device in accordance with an embodiment.

FIG. 3 is a perspective view of an illustrative electronic device such as a tablet computer in accordance with an embodiment.

FIG. 4 is a perspective view of an illustrative electronic device such as a computer or other equipment with a display in accordance with an embodiment.

FIG. 5 is a schematic diagram of illustrative circuitry in an electronic device in accordance with an embodiment.

FIG. 6 is a cross-sectional side view of an illustrative electronic device in accordance with an embodiment.

FIG. 7 is a cross-sectional side view of a flexible printed circuit in accordance with an embodiment.

FIG. 8 is a cross-sectional side view of a portion of a flexible printed circuit to which an electrical component has been mounted in accordance with an embodiment.

FIG. 9 is a cross-sectional side view of a flexible printed circuit having a single layer of patterned metal traces in accordance with an embodiment.

FIG. 10 is a cross-sectional side view of a flexible printed circuit having patterned metal traces formed on opposing upper and lower surfaces of a polymer substrate layer in accordance with an embodiment.

FIG. 11 is a cross-sectional side view of an illustrative flexible printed circuit in accordance with an embodiment.

FIG. 12 is a cross-sectional side view of an illustrative conductive via in a flexible printed circuit in accordance with an embodiment.

FIG. 13 is a schematic diagram of illustrative equipment that may be used in processing structures in accordance with an embodiment.

FIG. 14 is a cross-sectional side view of an illustrative electronic device that includes a strain gauge on a flexible printed circuit in accordance with an embodiment.

FIG. 15 is a cross-sectional side view of an illustrative electronic device having an electronic component such as a fingerprint sensor on a flexible printed circuit with a strain gauge in accordance with an embodiment.

FIG. 16 is a circuit diagram of illustrative strain gauge circuitry that forms a strain gauge in accordance with an embodiment.

FIG. 17 is a cross-sectional side view of an illustrative strain gauge sensor mounted to the underside of a component that covers an opening in a printed circuit in accordance with an embodiment.

FIG. 18 is a flow chart of illustrative steps involved in forming a flexible printed circuit with a strain gauge of the type shown in FIG. 17 in accordance with an embodiment.

FIG. 19 is a cross-sectional side view of an illustrative flexible printed circuit substrate with an opening that has been temporarily bridged by a support structure to facilitate mounting of a strain gauge sensor in the flexible printed circuit in accordance with an embodiment.

FIG. 20 is a cross-sectional side view of the illustrative flexible printed circuit substrate of FIG. 19 following removal of the support structure in accordance with an embodiment.

FIG. 21 is a cross-sectional side view of a strain gauge sensor mounted in an opening in a flexible printed circuit substrate and supported by a layer of flexible printed circuit material covering the opening in accordance with an embodiment.

FIG. 22 is a cross-sectional side view of an illustrative strain gauge sensor in a flexible printed circuit opening that is covered by a component in accordance with an embodiment.

FIG. 23 is a flow chart of illustrative steps involved in forming a flexible printed circuit of the type shown in FIG. 22 in accordance with an embodiment.

FIG. 24 is a cross-sectional side view of an illustrative flexible printed circuit substrate in accordance with an embodiment.

FIG. 25 is a cross-sectional side view of the illustrative flexible printed circuit substrate of FIG. 24 following the formation of metal traces and the mounting of a strain gauge sensor in accordance with an embodiment.

FIG. 26 is a cross-sectional side view of the illustrative flexible printed circuit of FIG. 25 following attachment of an electrical component that overlaps the strain gauge sensor in accordance with an embodiment.

FIG. 27 is a flow chart of illustrative steps involved in forming a flexible printed circuit of the types shown in FIG. 26 in accordance with an embodiment.

### DETAILED DESCRIPTION

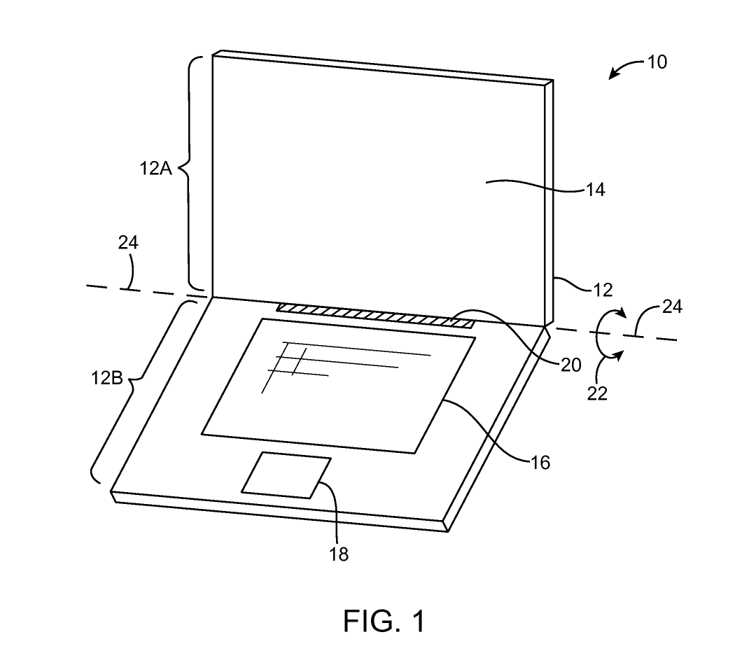

Electronic devices may be provided with printed circuits. The printed circuits may include rigid printed circuit boards (e.g., printed circuits formed from rigid printed circuit board material such as fiberglass-filled epoxy) and flexible printed circuits (e.g., printed circuits that include one or more sheets of polyimide substrate material or other flexible polymer layers). The flexible printed circuits may be provided with strain gauges. Illustrative electronic devices that may be provided with flexible printed circuits having strain gauges are shown in FIGS. 1, 2, 3, and 4.

Electronic device 10 of FIG. 1 has the shape of a laptop computer and has upper housing 12A and lower housing 12B with components such as keyboard 16 and touchpad 18. Device 10 has hinge structures 20 (sometimes referred to as a clutch barrel) to allow upper housing 12A to rotate in directions 22 about rotational axis 24 relative to lower housing 12B. Display 14 is mounted in housing 12A. Upper housing 12A, which may sometimes referred to as a display housing or lid, is placed in a closed position by rotating upper housing 12A towards lower housing 12B about rotational axis 24.

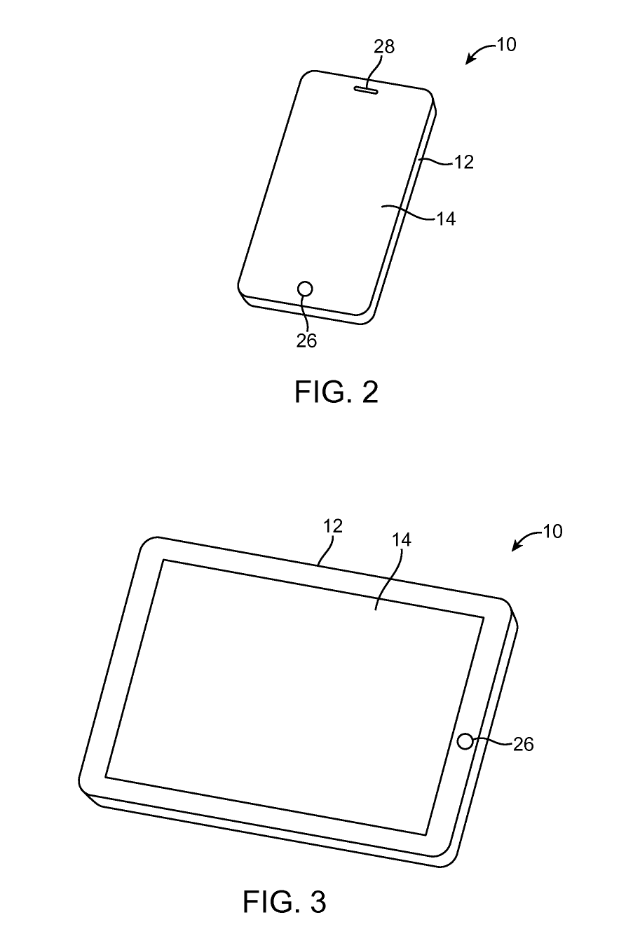

FIG. 2 shows an illustrative configuration for electronic device 10 based on a handheld device such as a cellular telephone, music player, gaming device, navigation unit, or other compact device. In this type of configuration for device 10, device 10 has opposing front and rear surfaces. The rear surface of device 10 may be formed from a planar portion of housing 12. Display 14 forms the front surface of device 10. Display 14 may have an outermost layer that includes openings for components such as button 26 and speaker port 28.

In the example of FIG. 3, electronic device 10 is a tablet computer. In electronic device 10 of FIG. 3, device 10 has opposing planar front and rear surfaces. The rear surface of device 10 is formed from a planar rear wall portion of housing 12. Curved or planar sidewalls may run around the periphery of the planar rear wall and may extend vertically upwards. Display 14 is mounted on the front surface of device 10 in housing 12. As shown in FIG. 3, display 14 has an outermost layer with an opening to accommodate button 26.

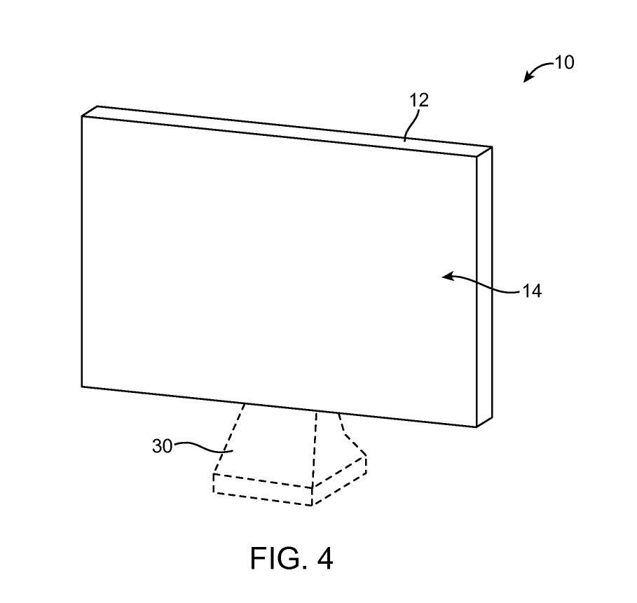

FIG. 4 shows an illustrative configuration for electronic device 10 in which device 10 is a computer display, a computer that has an integrated computer display, or a television. Display 14 is mounted on a front face of device 10 in housing 12. With this type of arrangement, housing 12 for device 10 may be mounted on a wall or may have an optional structure such as support stand 30 to support device 10 on a flat surface such as a table top or desk.

An electronic device such as electronic device 10 of FIGS. 1, 2, 3, and 4, may, in general, be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. The examples of FIGS. 1, 2, 3, and 4 are merely illustrative.

Device 10 may include a display such as display 14. Display 14 may be mounted in housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of display pixels formed from liquid crystal display (LCD) components, an array of electrophoretic display pixels, an array of plasma display pixels, an array of organic light-emitting diode display pixels, an array of electrowetting display pixels, or display pixels based on other display technologies.

Display 14 may be protected using a display cover layer such as a layer of transparent glass or clear plastic. Openings may be formed in the display cover layer. For example, an opening may be formed in the display cover layer to accommodate a button, an opening may be formed in the display cover layer to accommodate a speaker port, etc.

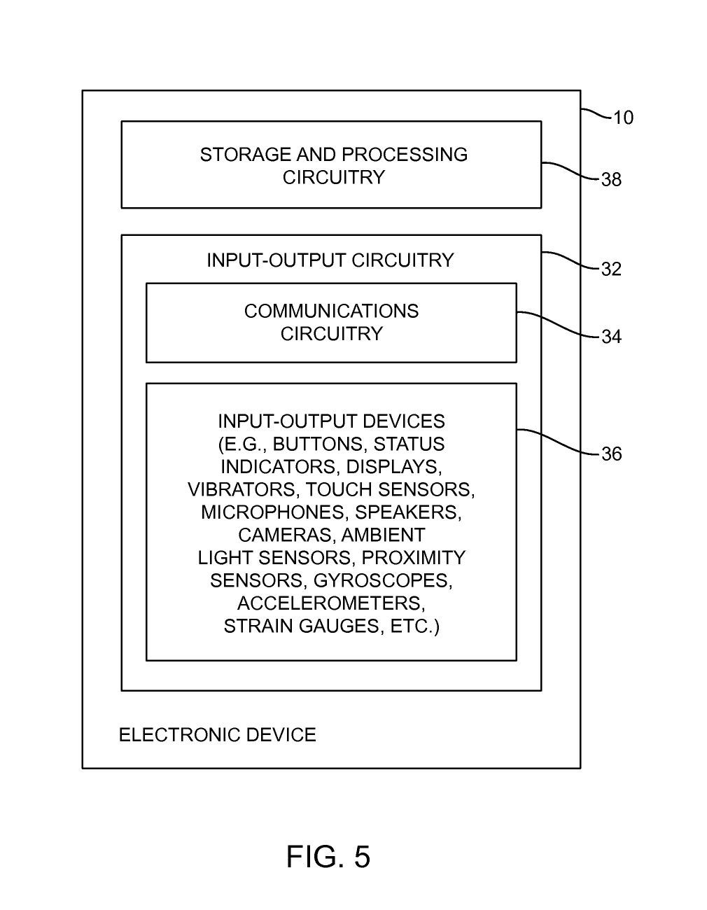

A schematic diagram of an illustrative device such as devices 10 of FIGS. 1, 2, 3, and 4 is shown in FIG. 5. As shown in FIG. 5, electronic device 10 may include control circuitry such as storage and processing circuitry 38. Storage and processing circuitry 38 may include one or more different types of storage such as hard disk drive storage, nonvolatile memory (e.g., flash memory or other electrically-programmable-read-only memory), volatile memory (e.g., static or dynamic random-access-memory), etc. Processing circuitry in storage and processing circuitry 38 may be used in controlling the operation of device 10. The processing circuitry may be based on a processor such as a microprocessor and other suitable integrated circuits. With one suitable arrangement, storage and processing circuitry 38 may be used to run software on device 10, such as internet browsing applications, email applications, media playback applications, operating system functions, software for capturing and processing images, software implementing functions associated with gathering and processing sensor data such as stress data, etc.

Input-output circuitry 32 may be used to allow data to be supplied to device 10 and to allow data to be provided from device 10 to external devices. Input-output circuitry 32 may include wired and wireless communications circuitry 34. Communications circuitry 34 may include radio-frequency (RF) transceiver circuitry formed from one or more integrated circuits, power amplifier circuitry, low-noise input amplifiers, passive RF components, one or more antennas, and other circuitry for handling RF wireless signals. Wireless signals can also be sent using light (e.g., using infrared communications).

Input-output circuitry 32 may include input-output devices 36. Input-output devices 36 may include devices such as buttons (see, e.g., button 26 of FIGS. 2 and 3), joysticks, click wheels, scrolling wheels, a touch screen (see, e.g., display 14), other touch sensors such as track pads (see, e.g., track pad 18 of FIG. 1), touch-sensor-based buttons, vibrators, audio components such as microphones and speakers, image capture devices such as a camera module having an image sensor and a corresponding lens system, keyboards, status-indicator lights, tone generators, key pads, strain gauges (e.g., a button based on a strain gauge), proximity sensors, ambient light sensors, capacitive proximity sensors, light-based proximity sensors, gyroscopes, accelerometers, magnetic sensors, temperature sensors, fingerprint sensors, and other equipment for gathering input from a user or other external source and/or generating output for a user.

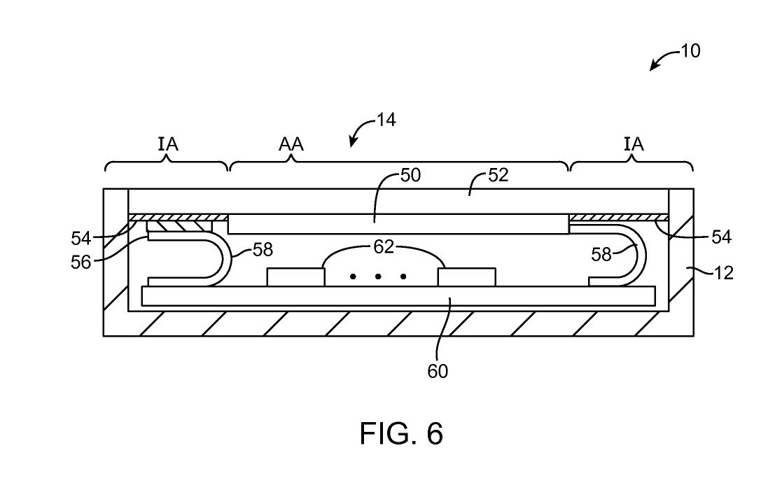

A cross-sectional side view of an illustrative electronic device of the type that may be provided with one or more flexible printed circuits is shown in FIG. 6. As shown in the illustrative configuration of FIG. 6, device 10 may have a display such as display 14 that is mounted on the front face of device 10. Display 14 may have a display cover layer such as cover layer 52 and a display module such as display module 50. Display cover layer 52 may be formed from a glass or plastic layer. Display module 50 may be, for example, a liquid crystal display module or an organic light-emitting diode display layer (as examples). Display module 50 may have a rectangular outline when viewed from the front of device 10 and may be mounted in a central rectangular active area AA on the front of device 10. An inactive area IA that forms a border for display 14 may surround active area AA. Opaque masking material such as black ink 54 may be used to coat the underside of cover layer 52 in inactive area IA.

Device 10 may include components such as components 62 that are mounted on one or more printed circuit boards such as printed circuit board 60. Printed circuit board 60 may have one or more layers of dielectric material and one or more layers of metal traces. Printed circuit board 60 of FIG. 6 may be a rigid printed circuit board or a flexible printed circuit board. Components 62 may be, for example, integrated circuits, discrete components such as capacitors, resistors, and inductors, switches, connectors, sensors, input-output devices such as status indicators lights, audio components, or other electrical and/or mechanical components for device 10. Components 62 may be attached to printed circuit 54 using solder, welds, anisotropic conductive film or other conductive adhesives, or other conductive connections. One or more layers of patterned metal interconnects (i.e., copper traces or metal traces formed from other materials) may be formed within one or more dielectric layers in printed circuit board 60 to form signal lines that route signals between components 62.

If desired, device 10 may have components mounted on the underside of display cover layer 52 such as illustrative component 56 on opaque masking layer 54 in inactive area IA of device 10 of FIG. 6. Component 56 may be a touch sensor, a fingerprint sensor, a strain gauge sensor, a button, or other input-output device 36 (as examples).

Flexible printed circuits 58 may have layers of dielectric and layers of metal traces. The metal traces of flexible printed circuits 58 may be used to form signal paths to interconnect the circuitry of device 10. For example, flexible printed circuits 58 may have signal paths that interconnect component 56 to the circuitry of components 62 on printed circuit 60, signal path that couple display module 50 to components 62 on printed circuit 60, or signal paths for interconnecting other components in device 10. Strain gauge structures such as strain gauge resistors may also be formed in flexible printed circuits 58. The strain gauge resistors (sometimes referred to as strain gauge sensors or strain gauges) may be formed from a semiconductor strain gauge structure such as a piece of silicon. A thin strip of silicon may, for example, be contacted by two conductive metal paths at opposing ends. When the silicon bends, the resistance measured between the two metal paths changes in proportion to the amount of strain imparted to the silicon. Semiconductor strain gauges such as silicon strain gauges may exhibit high gauge factors and other desired characteristics.

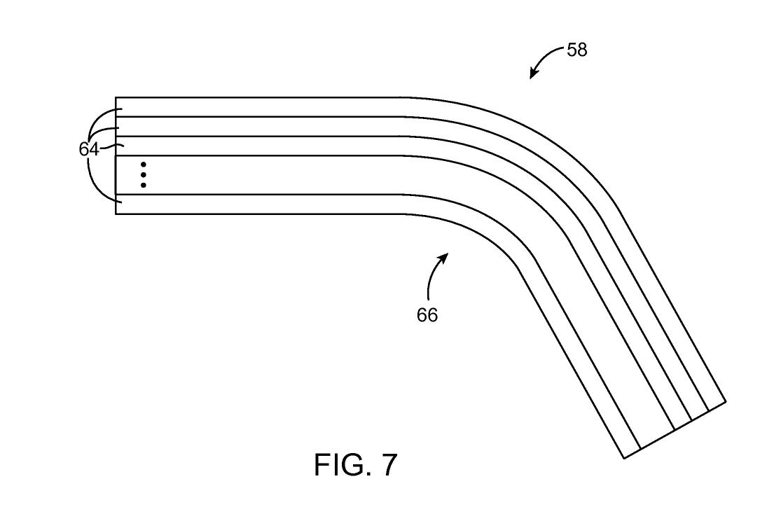

A cross-sectional side view of an illustrative flexible printed circuit is shown in FIG. 7. As shown in FIG. 7, flexible printed circuit 58 may have a bend such as bend 66. Flexible printed circuit 58 may include multiple layers of material such as layers 64. Layers 64 may include one or more metal layers, one or more dielectric layers, and one or more adhesive layers (or no adhesive layers). Metal traces formed from the metal layers may be used to carry electrical signals. Examples of metals that may be used in the metal layers of layers 64 in flexible printed circuit 58 include copper, nickel, gold, and aluminum. Examples of dielectric materials that may be used in forming the dielectric layers of layers 64 in flexible printed circuit 58 include polyimide, acrylic, and other polymers. Examples of adhesives that may be used in forming the adhesive layers of layers 64 in flexible printed circuit 58 include acrylic adhesives and epoxy adhesives. Other types of metal, dielectric, and adhesive may be used in forming layers 60 if desired. These are merely illustrative examples.

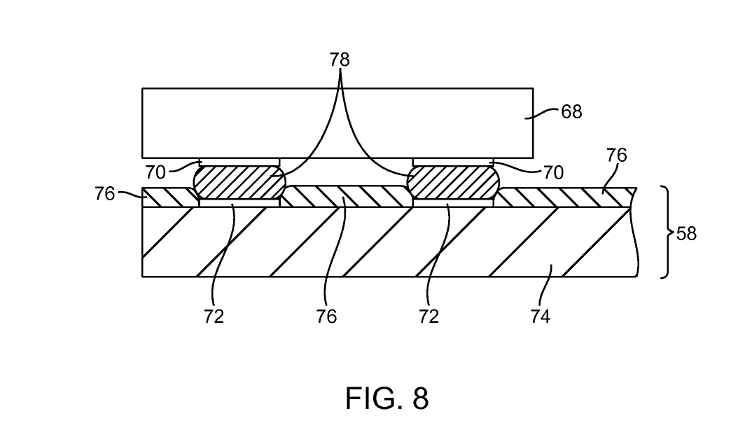

Electrical components such as illustrative electrical component 68 of FIG. 8 may be attached to flexible printed circuit 58. Components that may be attached to flexible printed circuit 58 in this way include connectors (e.g., all or part of a board-to-board connector, a zero insertion force connector, or other connector), integrated circuits, discrete components such as resistors, capacitors, and inductors, switching circuitry, and other circuitry (see, e.g., circuitry 38 and 32 of FIG. 5). Electrical and physical connections between component 68 and flexible printed circuit 58 may be made using solder, conductive adhesive, welds, or other conductive coupling mechanisms. In the illustrative configuration of FIG. 8, component 68 has metal contacts (solder pads) 70 and flexible printed circuit 58 has corresponding metal contacts (solder pads 72). A patterned dielectric layer such as a layer of polyimide or other polymer (sometimes referred to as a solder mask or cover layer) such as layer 76 may serve as the outermost layer of flexible printed circuit 58 (e.g., layer 76 may be formed on top of other layers in flexible printed circuit 58 such as the metal layer used in forming solder pads 72 and other layers 74 of metal, dielectric, and adhesive). If desired, a dielectric cover layer (e.g., a polyimide cover layer) may be formed on both the upper and lower surfaces of the layers of flexible printed circuit 58 (e.g., in a configuration in which metal traces are formed on upper and lower surfaces of an internal polyimide substrate layer). As shown in FIG. 8, openings in layer 76 may be formed to accommodate solder pads 72 and to help control the lateral spread of solder 70 when using solder 70 to solder component 68 to flexible printed circuit 58.

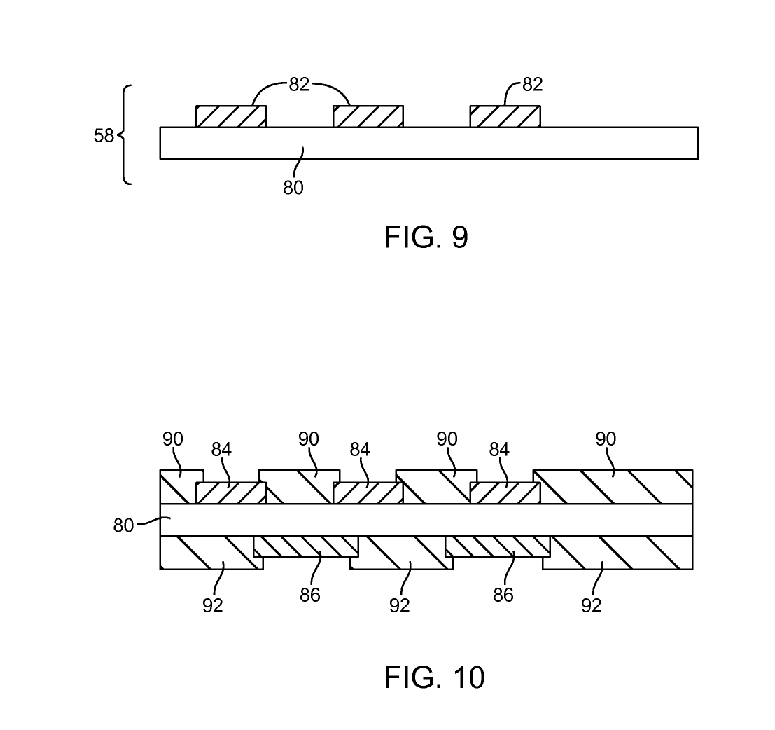

FIG. 9 shows how flexible printed circuit 58 may have signal paths formed from a patterned metal layer on a dielectric substrate. In the example of FIG. 9, flexible printed circuit 58 has a flexible dielectric substrate such as substrate 80 (e.g., a flexible polyimide layer) that has been covered with a patterned layer of metal traces 82 formed directly on the surface of substrate 80. If desired, additional layers of material (e.g., an adhesive layer, a polymer cover layer, etc.) may be formed on top of the flexible printed circuit 58 of FIG. 9 and/or below substrate 80. The FIG. 9 arrangement is a single-metal-layer flexible printed circuit. Flexible printed circuit configurations with two or more layers of metal may also be used.

FIG. 10 is a cross-sectional side view of flexible printed circuit 58 in a configuration in which flexible printed circuit 58 has been provided with two layers of patterned metal. As shown in FIG. 10, flexible printed circuit 58 has a polymer substrate such as a polyimide substrate (substrate 80). Substrate 80 has opposing upper and lower surfaces. Metal traces 84 of FIG. 10 are formed directly on the upper surface of substrate 80. Metal traces 86 are formed directly on the lower surface of substrate 80. A polymer cover layer such a layer 90 may be used to cover the upper metal layer used in forming metal traces 84. A polymer cover layer or other dielectric material 92 may be used to cover the lower metal layer used in forming metal traces 86. Openings may be formed in insulating layers such as polymer layers 90 and 92 (e.g., to allow components to be soldered to traces 84 and/or 86). A patterned dielectric layer such as a polymer layer with openings may also be formed over traces 82 of flexible printed circuit 58 of FIG. 9.

The outermost dielectric layers of flexible printed circuit 58 (i.e., the cover layers for flexible printed circuit 58) may be formed from a laminated polymer film (e.g., a polyimide film attached to flexible printed circuit 58 with a layer of adhesive), may be formed from a cured liquid polymer (e.g., photoimageable polymer formed directly on underlying layers without adhesive), or may be formed from other dielectric materials formed directly on underlying metal traces or other structures on the surface of printed circuit 58 and/or attached to underlying metal traces or other structures on the surface of printed circuit 58 using adhesive. Metal traces 82 may be formed directly on the surface of substrate 80 as shown in the examples of FIGS. 9 and 10 or may be laminated to substrate 80 using adhesive. For example, traces 82 in FIG. 9 may be formed by laminating a metal foil layer to substrate 80 with an interposed layer of adhesive). If desired, three or more metal layers may be formed in flexible printed circuit 58, as described in connection with FIG. 7. In configurations for printed circuit 58 that contain multiple metal layers, multiple intervening substrate layers may, if desired, be used to separate metal layers. For example, there may be two or more polyimide substrate layers in printed circuit 58. Adhesive layers, metal layers, substrate layers, and polymer cover layers (sometimes referred to as solder mask layers or coverlay) may be arranged in a stack in a desired pattern to form flexible printed circuit 58. The use of a single-layer design for flexible printed circuit 58 of FIG. 9 and a two-layer design for flexible printed circuit 58 of FIG. 10 is merely illustrative.

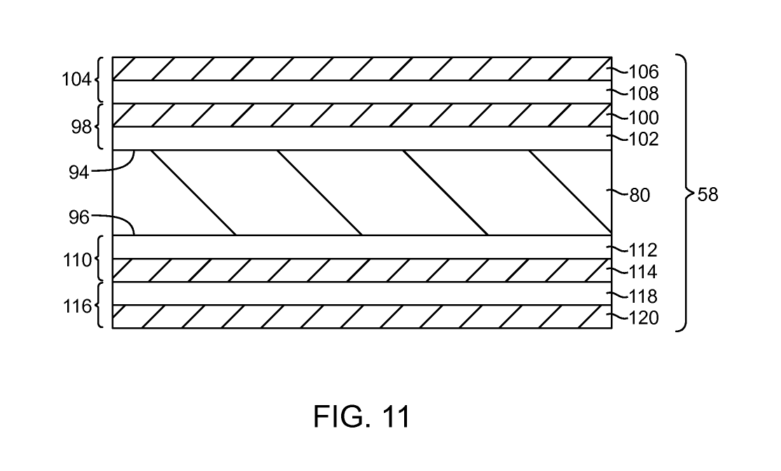

FIG. 11 is a cross-sectional side view of an illustrative two-layer flexible printed circuit showing how both the upper and lower surfaces of substrate 80 may be covered with layers of material that are attached to substrate 80 using adhesive. As shown in FIG. 11, flexible printed circuit 58 is formed using a substrate layer such as substrate 80 (e.g., a polyimide layer or other suitable layer). Substrate 80 has upper surface 94 and opposing lower surface 96. Layer 98 may be formed on upper surface 94. Layer 98 may include metal layer 100 and adhesive layer 102. Adhesive layer 102 may be used to laminate metal layer 100 to upper surface 94 of substrate 80. Layer 104 may be formed on top of layer 98. Layer 104 may include polymer layer 106 such as a polyimide layer (sometimes referred to as a cover layer, coverlay, or solder mask). Adhesive layer 108 in layer 104 may be used to attach polymer layer 106 to layer 98. The underside of flexible printed circuit substrate 80 may be provided with layers 110 and 116. Layer 110 may include metal layer 114. Adhesive layer 112 in layer 110 may be used to attach metal layer 114 to lower surface 96 of substrate 80. Layer 116 may include dielectric layer 120 (e.g., a polymer cover layer such as a polyimide layer) and adhesive layer 118 for attaching layer 120 to layer 110. Metal layers in flexible printed circuit 58 such as metal layer 114 and metal layer 100 of FIG. 11 may be patterned using photolithography, laser cutting, die cutting (e.g., foil stamping techniques), or other patterning techniques. Dielectric layers 106 and 120 and/or the adhesive layers in flexible printed circuit 58 may also be patterned using these techniques.

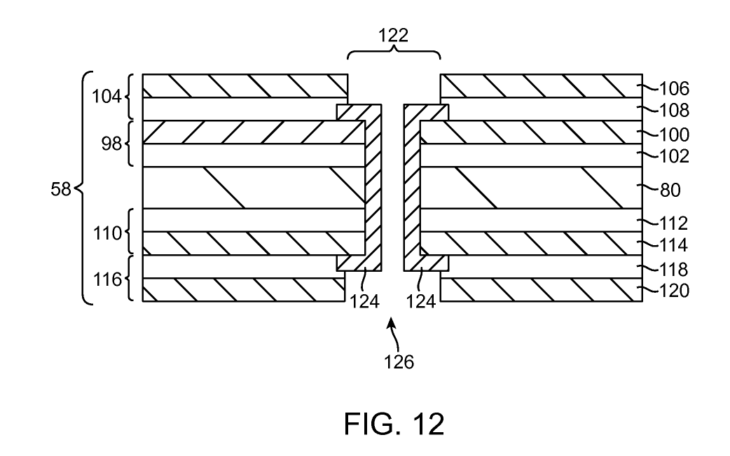

If desired, through vias, blind vias, and buried vias may be used to interconnect metal traces on different layers of flexible printed circuit 58. Holes or other openings may be formed in flexible printed circuit 58 using laser drilling, stamping, machining, or other hole formation techniques. The holes may be filled with metal using electroplating, electroless deposition, or other metal deposition techniques. Plated holes may form tubular vias that form conductive signal paths between the metal layers of flexible printed circuit 58. As shown in FIG. 12, for example, the layers of flexible printed circuit 58 may be provided with holes such as hole 122. Metal 124 may be deposited on the inner surface of hole 122 using electrochemical deposition (e.g., electroplating and/or electroless deposition), thereby forming via 126. Via 126 can form a signal path between metal layer 100 and metal layer 114. Vias with other configurations (e.g., blind vias and buried vias) can likewise interconnect different metal layers in flexible printed circuit 58.

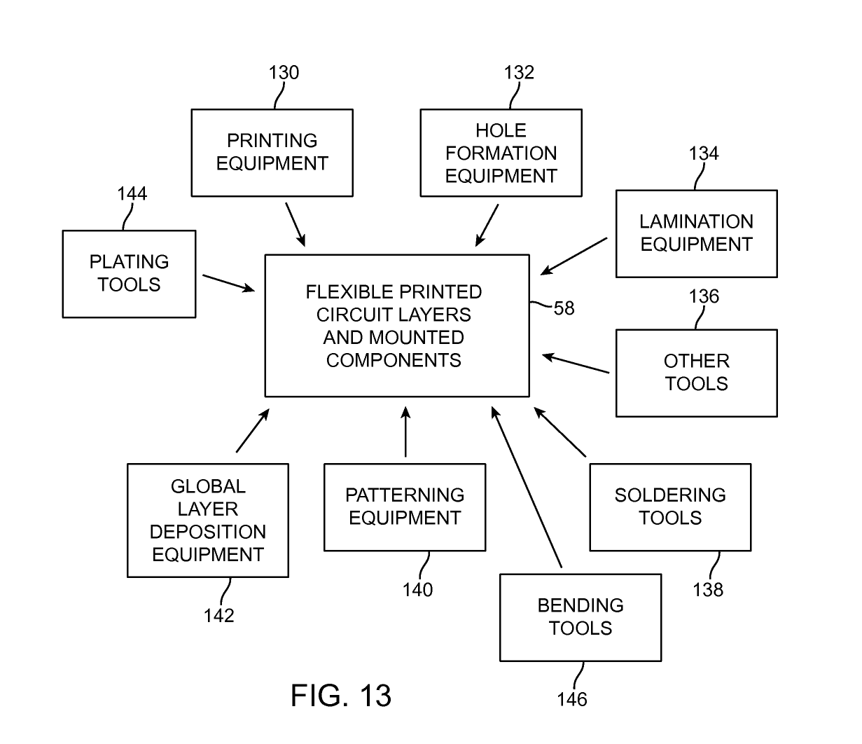

FIG. 13 is a diagram of illustrative processing equipment that may be used in forming flexible printed circuit 58 and in mounting electrical components to flexible printed circuit 58 or otherwise coupling flexible printed circuit 58 into the circuitry of device 10.

The equipment of FIG. 13 may include printing equipment 130. Printing equipment 130 may include ink jet printing equipment, pad printing equipment, screen printing equipment, and other equipment for printing blanket layers and/or patterned layers of material. Examples of structures that may be formed using equipment 130 include printed layers of dielectric, strips of dielectric, metal lines (e.g., metal traces formed from metallic paint or other liquid conductive material), blanket layers of metal, etc.

Hole formation equipment 132 may include tools such as laser drilling tools, machining tools, and other equipment for forming openings in one or more layers of material for flexible printed circuit 58. For example, hole formation equipment 132 may use a laser or other tool to drill holes for vias such as via 126 of FIG. 12.

Lamination equipment 134 may include rollers and other equipment for laminating layers of material together (e.g., using heat and pressure to cause adhesive to attach layers of flexible printed circuit 58 together or to otherwise attach layers together).

Global layer deposition equipment 142 may include equipment for depositing layers of material by blanket spray coating, by spinning, by physical vapor deposition (e.g., sputtering), or other deposition techniques.

Patterning equipment 140 may be used to pattern layers of material such as blanket layers of metal and/or dielectric. Equipment 140 may include photolithographic equipment such as equipment for depositing photoresist or other photoimageable materials, equipment for exposing photoresist or other photoimageable materials to patterned light associated with a photomask, developing equipment to use in developing photoresist or other photoimageable materials, etching equipment for etching the structures of flexible printed circuit 58 after deposited photoresist has been patterned by exposure and development, etc.

Electrochemical deposition tools 144 such as tools for electroplating metal in a via, tools for electroless deposition, and other electrochemical deposition equipment may be used in forming flexible printed circuit 58.

One or more of the layers of flexible printed circuit 58 and/or other structures may be bent using bending tools 146. Bending tools 146 may be formed from stand-alone equipment or equipment that is integrated into other equipment of FIG. 13. Examples of bending equipment that may be used in forming bends in flexible printed circuit 58 include mandrels, presses, grippers, and other bending machines.

If desired, other tools 136 may be used in processing the structures of flexible printed circuit 58 such as lasers for cutting, machining tools for trimming or cutting, heated presses, die cutting equipment, injection molding equipment, heating equipment such as infrared lamps and ovens, light-emitting diodes, or other light sources for adhesive curing (e.g., ultraviolet light-emitting diodes), and other equipment for depositing, patterning, processing, and removing layers of dielectric and metal for structures 58.

Soldering tools 138 and other equipment may be used in mounting electrical components to flexible printed circuit 58 and/or may be used in coupling flexible printed circuit 58 to other circuitry in device 10.

Strain gauge structures may be incorporated into a device such as device 10. A strain gauge may be used, for example, to implement a button. A strain gauge may be based on a network of resistors. One or more of the resistors may be formed from a semiconductor such as silicon that exhibits a change in resistance in proportion to applied strain. Semiconductor strain gauges such as these may exhibit enhanced performance (e.g., higher gauge factor) compared to strain gauges based on other types of strain-sensitive resistors such as metal resistors.

Strain gauge structures such as strain gauge resistors can be formed in a recessed portion of a flexible printed circuit such as flexible printed circuit 58 or may otherwise be incorporated into flexible printed circuit 58. This type of arrangement conserves space within device 10 and can improve performance and reduce complexity. In general, strain gauge structures for flexible printed circuit 58 may be based on semiconductor strain gauge structures (i.e., one or more strain-sensitive semiconductor resistors), may be based on metal resistor strain gauge structures, or may be based on other strain gauge structures. Configurations in which flexible printed circuit 58 is provided with a semiconductor strain gauge are sometimes described here as an example. This is, however, merely illustrative. Any suitable strain gauge may be incorporated into flexible printed circuit 58, if desired.

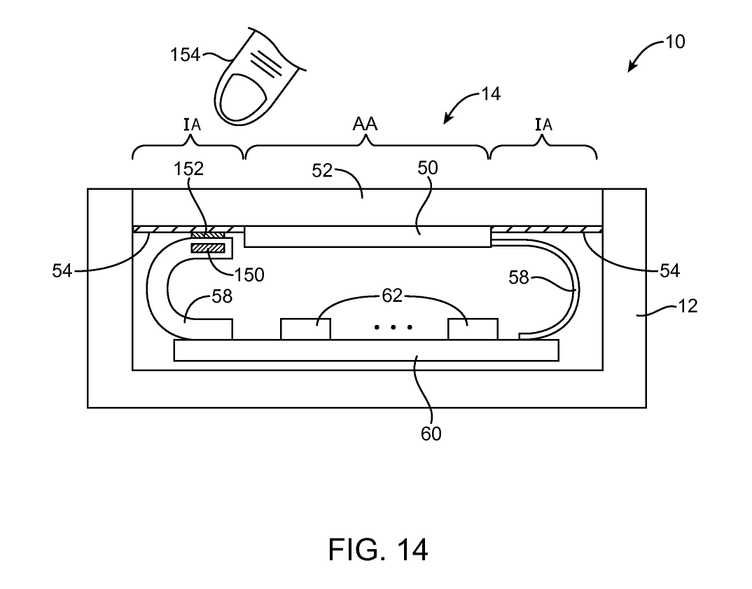

An illustrative configuration for device 10 in which a flexible printed circuit has been provided with a semiconductor strain gauge (e.g., one or more semiconductor strain gauge resistors) is shown in FIG. 14. As shown in the cross-sectional side view of device 10 in FIG. 14, device 10 may have display 14 mounted in housing 12. Display 14 may include display cover layer 52. Display 14 may have display module 50 in active area AA. Inactive area IA may form a border that runs around the periphery of active area AA. Opaque masking material 54 (e.g., black ink) may be formed on the inner surface of cover layer 52 in inactive area IA.

Device 10 may include components such as components 62 that are mounted on one or more printed circuit boards such as printed circuit board 60. In the illustrative configuration of FIG. 14, the flexible printed circuit 58 that is on the right-hand side of device 10 is used to couple the circuitry of printed circuit board 60 to display module 58. The flexible printed circuit 58 that is on the left-hand side of device 10 includes strain gauge structure 150. Strain gauge structure 150 may be, for example, a semiconductor strain gauge that includes one or more semiconductor resistors (e.g., silicon resistors). The strain gauge resistors may form the sensing portion of a strain gauge and may be mounted at a location in device 10 that is subject to strain. For example, portion of flexible printed circuit 58 containing the strain gauge resistors of structure 150 may be mounted to the underside of display cover layer 52 using adhesive 152. In the presence of pressure from an external object such as a user's finger (finger 154), the strain gauge resistors of structure 150 may exhibit a change in resistance. By detecting finger pressure on display cover layer 52 in this way, the strain gauge structure may be used to implement a thin strain gauge button for device 10. The absence of strain indicates that the user's finger is not pressing down on the strain gauge button. The presence of strain indicates that the user's finger is pressing down on the strain gauge button. If desired, the strain gauge button may also be used to measure intermediate amounts of strain (e.g., to implement a volume control function or other analog control device).

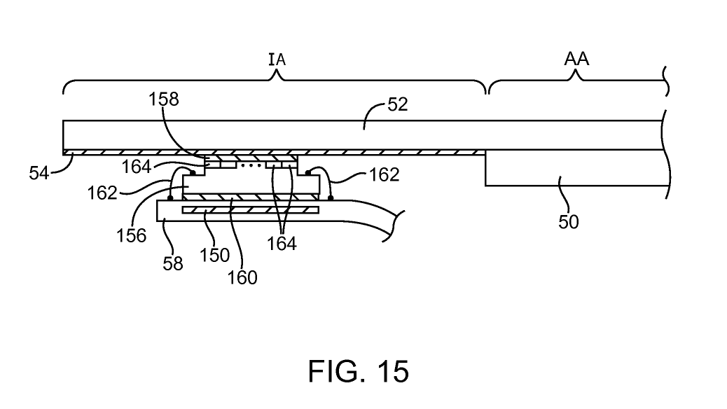

If desired, a fingerprint sensor may be provided in device 10. For example, a fingerprint sensor may overlap strain gauge structure 150. The fingerprint sensor may have electrodes or other structures that are formed in flexible printed circuit 58. As shown in FIG. 15, the fingerprint sensor may, if desired, be implemented using a fingerprint sensor device (e.g., a silicon die) such as fingerprint sensor 156 that is mounted to flexible printed circuit 58. Fingerprint sensor 156 may have an array of fingerprint sensor electrodes such as electrodes 164. A layer of adhesive such as adhesive 158 may be used to attach the array of electrodes 164 and the other circuitry of fingerprint sensor 156 to the inner surface of display cover layer 52. Adhesive 160 may be used to attach fingerprint sensor 156 to flexible printed circuit 58. If desired, other attachment mechanisms such as solder joints, welds, and fasteners, may be used in mounting flexible printed circuit 58 and fingerprint sensor 156 within device 10. The use of adhesive layers such as adhesive layer 158 and adhesive layer 160 is merely illustrative.

Signals may be routed between fingerprint sensor 156 and traces on flexible printed circuit 58 using solder joints, conductive adhesive connections, or wire-bond connections formed by wire bonds such as wires bonds 162 of FIG. 15.

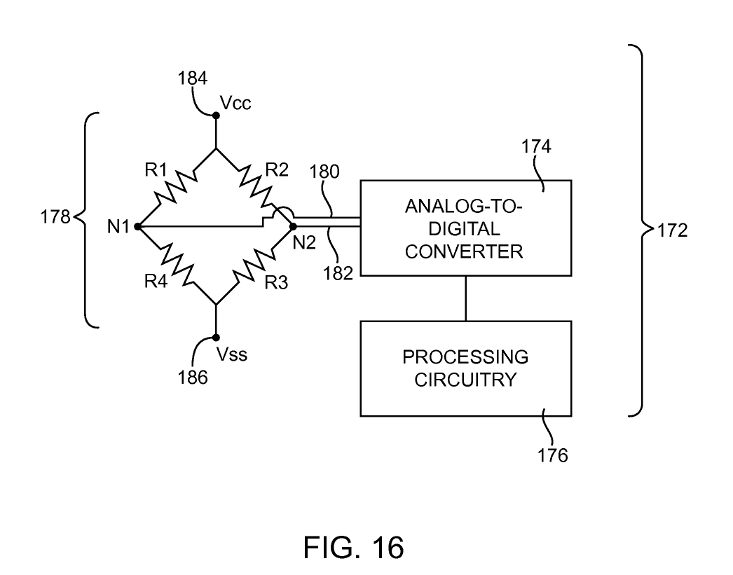

A Wheatstone bridge or other strain gauge circuitry may be used to measure resistance changes in the semiconductor strain gauge resister(s) of the strain gauge. An illustrative strain gauge circuit that may be used in monitoring strain-induced resistance changes in the strain-sensitive strain gauge resistor(s) of strain gauge structures such as strain gauge structure 150 of FIG. 15 is shown in FIG. 16. Strain gauge circuitry 172 of FIG. 16 includes strain gauge resistors R1, R2, R3, and R4. One or more of strain gauge resistors R1, R2, R3, and R4 may be implemented using a semiconductor strain gauge resistor that is sensitive to strain, so circuitry such as circuit 172 is sometimes referred to as a semiconductor strain gauge.

Semiconductor strain gauge circuitry 172 may include an analog-to-digital converter such as analog-to-digital converter 174 and processing circuitry 176. Analog-to-digital converter 174 and 176 may be implemented using integrated circuits mounted to flexible printed circuit 58 or to elsewhere in device 10.

Analog-to-digital converter circuitry 174 may be coupled to a bridge circuit such as bridge circuit 178 that is formed from resistors R1, R2, R3, and R4 using signal paths 180 and 182. A power supply may provide a power supply voltage Vcc to bridge circuit terminal 184 of bridge circuit 178 and may provide a power supply voltage Vss to bridge circuit terminal 186 of bridge circuit 178. Power supply voltages Vcc and Vss may be, for example, a positive power supply voltage and a ground power supply voltage, respectively.

During operation of strain gauge circuitry 172, a voltage drop of Vcc-Vss will be applied across bridge circuit 178. Resistors R1, R2, R3, and R4 may all nominally have the same resistance value (as an example). In this configuration, bridge circuit 178 will serve as a voltage divider that nominally provides each of paths 180 and 182 with a voltage of (Vcc-Vss)/2. The voltage difference across nodes N1 and N2 will therefore initially be zero.

With one suitable arrangement, semiconductor resistors R1 and R3 are mounted in flexible printed circuit 58 so that both resistors R1 and R3 will experience similar stresses during use. Resistors R2 and R4 (which may be formed using non-semiconductor resistor structures) may be located away from resistors R1 and R3 and/or may be oriented so as to avoid being stressed while resistors R1 and R3 are being stressed. This allows resistors R2 and R4 to serve as reference resistors. With this approach, pressure to the strain gauge resistors R1 and R3 in flexible printed circuit 56 from user finger 164 will cause the resistance of resistors R1 and R3 to rise simultaneously while resistors R2 and R4 serve as nominally fixed reference resistors (compensating for drift, temperature changes, etc.). Other types of bridge circuit layout may be used if desired. For example, bridge circuit 178 may be implemented using a single strain-sensing resistor (e.g., resistor R1) and three fixed resistors (e.g., R2, R3, and R4), etc.

Due to the changes in resistance to one or more strain-sensitive semiconductor resistors in circuit 178, the voltage between paths 180 and 182 will vary in proportion to the strain that is being applied to the strain gauge structure 150. Analog-to-digital converter 174 digitizes the voltage signal across paths 180 and 182 and provides corresponding digital strain (stress) data to processing circuitry 176. Processing circuitry 176 and other control circuitry in device 10 can take appropriate action in response to the measured strain data. For example, processing circuitry 176 can convert raw strain data into button press data or other button input information. Device 10 can then respond accordingly (e.g., by using the strain gauge button data as button press data for a menu or home button, etc.).

Strain gauge circuitry 172 such as analog-to-digital converter 174 and processing circuitry 176 may be mounted on board 60 (i.e., analog-to-digital converter 174 and processing circuitry 176 may be implemented in one or more components 62 on board 60) and/or circuitry such as analog-to-digital converter 174 and processing circuitry 176 may be mounted on flexible printed circuit 58 (e.g., using solder, wire bonds, etc.). Signal paths such as paths 180 and 182 may run between nodes N1 and N2 in bridge circuit 178 and analog-to-digital converter 174. To form low-resistance paths that are not subject to changes due to variations in strain, signal paths in strain gauge circuitry 172 such as paths 180 and 182 are preferably formed from low-resistivity materials such as copper. Wire bonds, solder connections, and other connections may be used to interconnect the strain gauge resistor(s) to circuitry 174. Connections such as these may also be used in mounting electrical components such as fingerprint sensor 156 over the strain gauge resistor(s).

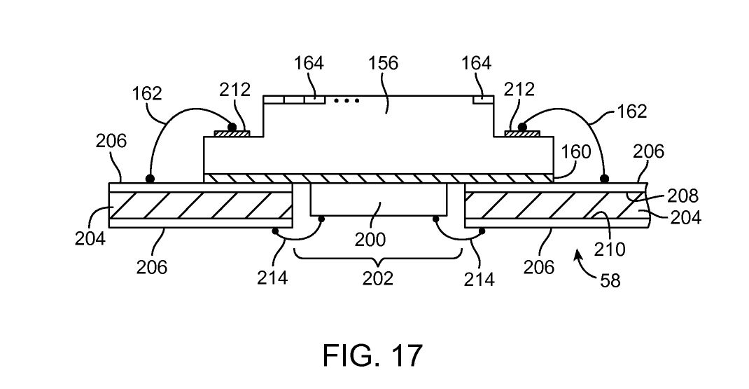

A semiconductor strain gauge (i.e., one or more strain-sensing semiconductor strain gauge resistors) may be mounted in a recess or other opening in flexible printed circuit 58 or may otherwise be incorporated into flexible printed circuit 58. As shown in FIG. 17, for example, flexible printed circuit 58 may be provided with an opening such as opening 202 into which semiconductor strain gauge 200 may be mounted. Flexible printed circuit 58 may have one or more flexible dielectric layers. As an example, flexible printed circuit 58 may include a flexible polyimide layer or other flexible polymer layer such as flexible polymer substrate layer 204. Flexible polymer substrate layer 204 may have an upper surface such as upper surface 208 and an opposing lower surface such as lower surface 210. Metal traces 206 may be formed on upper surface 208 and/or lower surface 210. Traces 206 may be patterned to form paths such as signal paths 180 and 182 of FIG. 16. Traces 206 may be formed directly on surfaces 208 and/or 210 and/or may be attached to surfaces 208 and/or 210 using adhesive.

Semiconductor strain gauge 200 may include one or more semiconductor resistors for bridge circuit 178. For example, semiconductor strain gauge 200 may form one or more strain-sensing silicon resistors. Electrical connections such as wire bonds 214 or other signal paths may be used to couple traces 206 to semiconductor strain gauge 200.

An electrical component such as component 156 may be mounted on flexible printed circuit 58. Component 156 may be a fingerprint sensor having an array of electrodes 164. Wire bonds 162 or other signal paths may be used to couple metal traces 212 on fingerprint sensor 156 to metal traces 206 on flexible printed circuit substrate 204.

Fingerprint sensor 156 may be mounted over opening 202 in flexible printed circuit 58 using adhesive layer 160. A portion of adhesive layer 160 on the lower surface of fingerprint sensor 156 may be exposed in opening 202. Semiconductor strain gauge 200 may be attached to adhesive layer 160. If desired, a layer of dielectric (e.g., a polymer layer such as a layer of polyimide) may be interposed between fingerprint sensor 156 and opening 202. The example of FIG. 17 is merely illustrative.

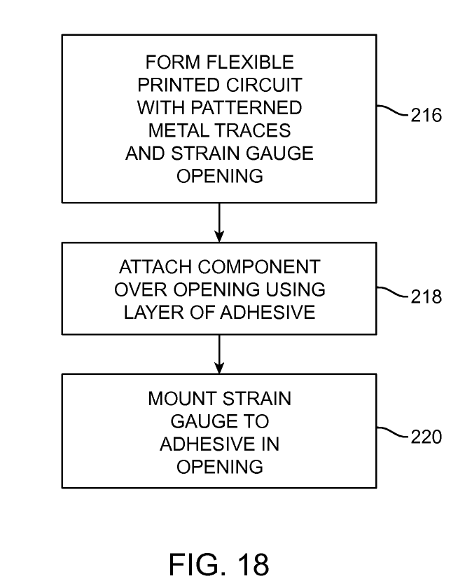

Illustrative steps involved in forming a flexible printed circuit with a semiconductor strain gauge such as strain gauge 200 are shown in FIG. 18.

At step 216, flexible printed circuit 58 may be provided with patterned metal traces and one or more openings. For example, cutting equipment may be used to form openings such as opening 202 in substrate 204 and photolithography or printing techniques may be used in forming patterned metal traces 206 on substrate 204. Metal traces 206 may, if desired, be formed by laminating metal foil to substrate 204, by printing metal paint onto substrate 204, etc.

The flexible printed circuit layers of flexible printed circuit 56 may include one or more metal layers, dielectric layers, and adhesive layers. If desired, adhesive layers may be used in attaching metal layers to dielectric layers and may be used in attaching substrate layers, cover layers, and other dielectric layers within flexible printed circuit 56. Openings such as opening 202 may be formed by laser cutting, knife cutting, stamping, etching, or other techniques. Openings such as opening 202 may pass completely through flexible printed circuit 58 (e.g., through substrate layer 204 and any additional substrate layers in flexible printed circuit 58) or may pass only part way through flexible printed circuit 58 to form a recess with a closed bottom. Openings such as opening 202 may be sized to accommodate a strain gauge structure such as structure 200 and may therefore sometimes be referred to as strain gauge openings.

At step 218, an electrical component such as fingerprint sensor 156 may be attached over opening 202 using adhesive layer 160 (i.e., opening 202 may be overlapped by sensor 156) or may otherwise be mounted to flexible printed circuit substrate 204 in a configuration that overlaps strain gauge sensor 200. Exposed portions of adhesive layer 160 may be present on the lower surface of sensor 156.

At step 220, strain gauge 200 may be mounted on the exposed portion of adhesive layer 160. If desired, additional adhesive (e.g., liquid adhesive) may be placed in the cavity formed by opening 202 to help secure strain gauge 200 within opening 202. For example, strain gauge 200 may be mounted in opening 202 using two-part epoxy or other adhesive.

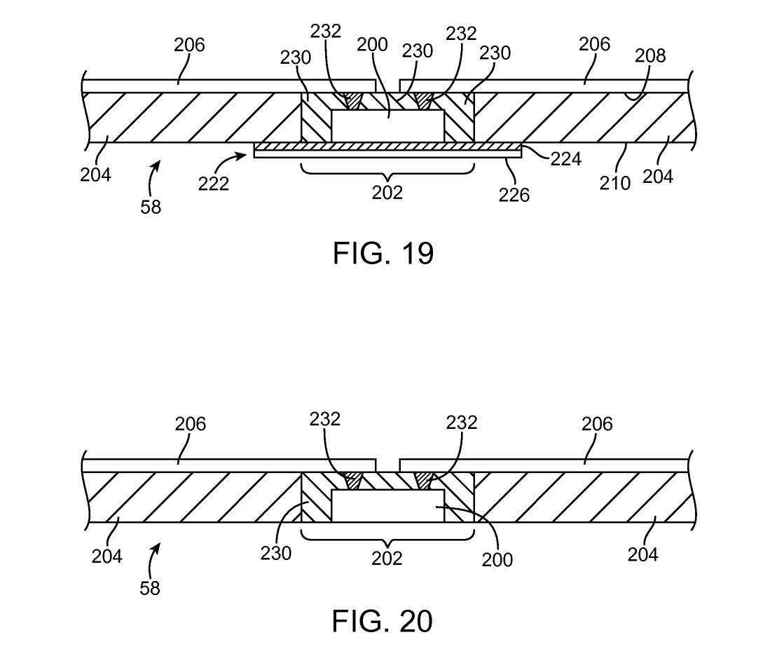

It may be desirable to form signal paths to strain gauge 200 by extending patterned metal traces 206 over strain gauge 200. This type of arrangement is shown in FIGS. 19 and 20.

Initially, opening 202 may be formed in flexible printed circuit substrate 204. A support structure may then be used to cover the bottom of opening 202. For example, tape 222 may be placed over opening 202 on lower surface 210 of substrate 204. Tape 222 may have a flexible carrier layer such as flexible polymer carrier layer 226 and an adhesive layer such as adhesive layer 224. Adhesive layer 224 may be used to attach tape 222 to lower surface 210. Strain gauge 200 may then be mounted on the exposed portion of adhesive 224 that is present in opening 202. Encapsulant (e.g., a polymer adhesive such as epoxy or other liquid adhesive) such as encapsulant 230 may be used to fill opening 202. Encapsulant 230 may be cured using ultraviolet light, heat that produces elevated temperatures, or room-temperature curing.

Vias such as vias 232 may be used to form electrical connections between the exposed upper surface of cured encapsulant layer 230 and strain gauge sensor 200. Vias 232 may be drilled using a laser drilling tool or other hole formation equipment and may be partly or entirely filled with a conductive material such as metal to form an interconnect path between strain gauge 200 and metal traces on flexible printed circuit 58. Following via formation, metal traces 206 may be formed on upper surface 208 of flexible printed circuit substrate 204. Traces 206 overlap vias 232 and thereby form electrical connections to strain gauge 200.

After traces 206 have been formed, tape 222 may be removed from the lower surface of substrate 204, as shown in FIG. 20. Because adhesive encapsulant 230 has been cured, strain gauge 200 and encapsulant 230 will remain in opening 202. In the example of FIG. 20, one layer of metal traces 206 is formed on substrate 204. This is merely illustrative. Flexible printed circuit 58 may include any suitable number of metal traces (e.g., one or more, two or more, three or more, four or more, etc.).

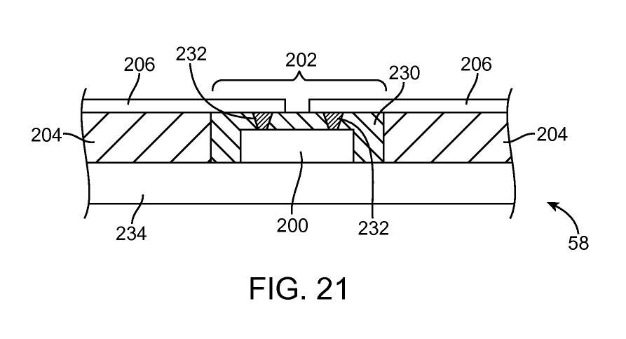

As shown in FIG. 21, additional flexible printed circuit layers such as layer(s) 234 may be provided below substrate 204. Layer(s) 234 may include one or more flexible printed circuit substrate layers such as one or more flexible polyimide substrate layers, one or more adhesive layers, and/or one or more patterned metal trace layers. In a configuration of the type shown in FIG. 21, substrate 234 may serve as a support for strain gauge 200, so tape 222 of FIG. 19 need not be used to support strain gauge 200. Opening 202 may be formed in substrate layer 204 (e.g., as a through hole) and layer 234 may be laminated to layer 204 or opening 202 may be created by etching a recess into a printed circuit substrate (as examples).

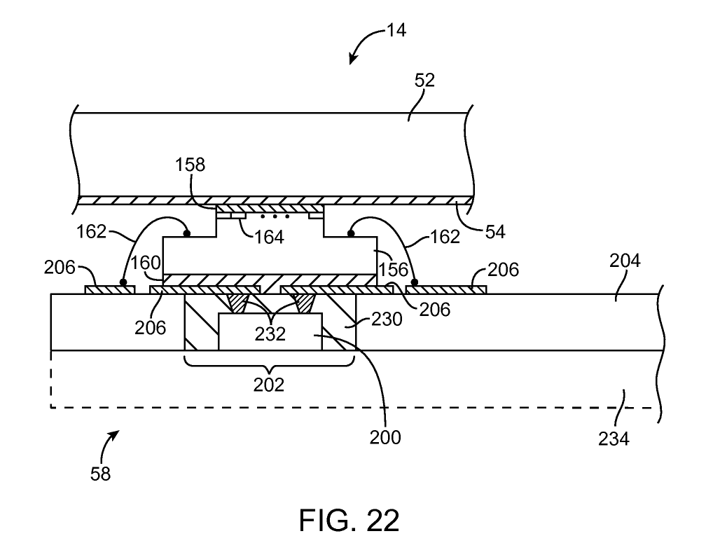

FIG. 22 shows how fingerprint sensor 156 may be mounted to flexible printed circuit 58 and may be attached to the underside of display cover layer 52. Display cover layer 52 of display 14 may have an inner surface covered with opaque masking layer 54. Adhesive layer 158 may be used to mount fingerprint sensor 156 to layer 52 so that electrodes 164 are located adjacent to the inner surface of layer 52. Flexible printed circuit 58 may have flexible printed circuit substrate 204 (e.g., a polyimide substrate layer). Metal traces 206 may be patterned on the upper surface of layer 204 and may contact semiconductor strain gauge 200 through vias 232 in encapsulant 230. Wire bonds 162 may be used to connect fingerprint sensor 156 to metal traces 206. Any suitable pattern of interconnects may be formed from metal traces 206 and/or additional metal layers in flexible printed circuit 58. The example of FIG. 22 is merely illustrative. Additional flexible printed circuit layers 234 may be included in flexible printed circuit 58 if desired (e.g., one or more additional layers of metal traces, dielectric, and/or adhesive).

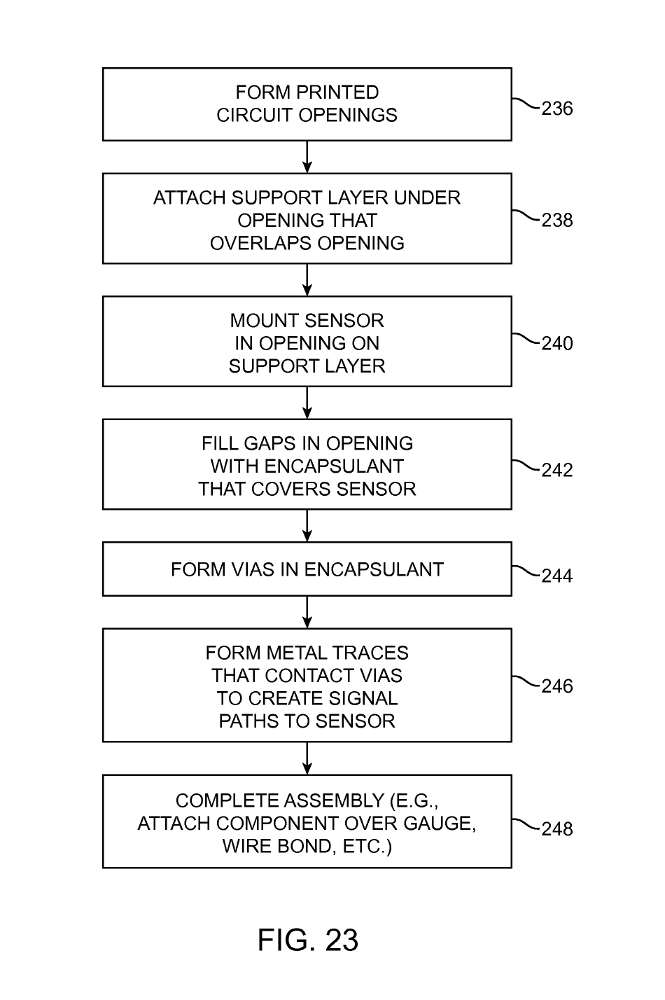

Illustrative steps involved in forming flexible printed circuit 58 with a semiconductor strain gauge that is mounted within a substrate opening such as opening 202 and that is contacted using vias are shown in FIG. 23.

At step 236, openings such as opening 202 are formed in flexible printed circuit layers such as substrate 204.

At step 238, a layer of tape such as tape 222 of FIG. 19 or other support structure may be used to cover opening 202 as shown in FIG. 19.

At step 240, semiconductor strain gauge 200 may be mounted in the opening. The tape or other support structure that covers the lower portion of opening 202 may serve as a temporary support structure or opening 202 may be formed from a recess in a flexible printed circuit that passes only partway into the flexible printed circuit.

While maintaining semiconductor strain gauge 200 within opening 202, polymer encapsulant 230 (e.g., epoxy or other liquid adhesive) may be introduced into opening 202 (step 242). Encapsulant 230 may fill the gaps between strain gauge 200 and the surrounding portions of flexible printed circuit substrate material and may encapsulate semiconductor strain gauge 200.

At step 244, laser drilling or other hole formation techniques are used to form holes through encapsulant 230 that reach strain gauge 200. Metal or other conductive material may be deposited into the holes to form vias 232 that contact semiconductor strain gauge 200.

At step 246, metal traces 206 are deposited and patterned onto the flexible printed circuit layers. In particular, traces 206 may be formed that contact vias 232, thereby forming signal paths in the interconnects of flexible printed circuit 58 that are coupled to semiconductor strain gauge 200.

At step 248, fingerprint sensor 156 or other electrical component may be mounted to flexible printed circuit 58, fingerprint sensor 156 and other portions of flexible printed circuit 58 may be attached to the underside of display cover layer 52, and other assembly operations in device 10 may be completed.

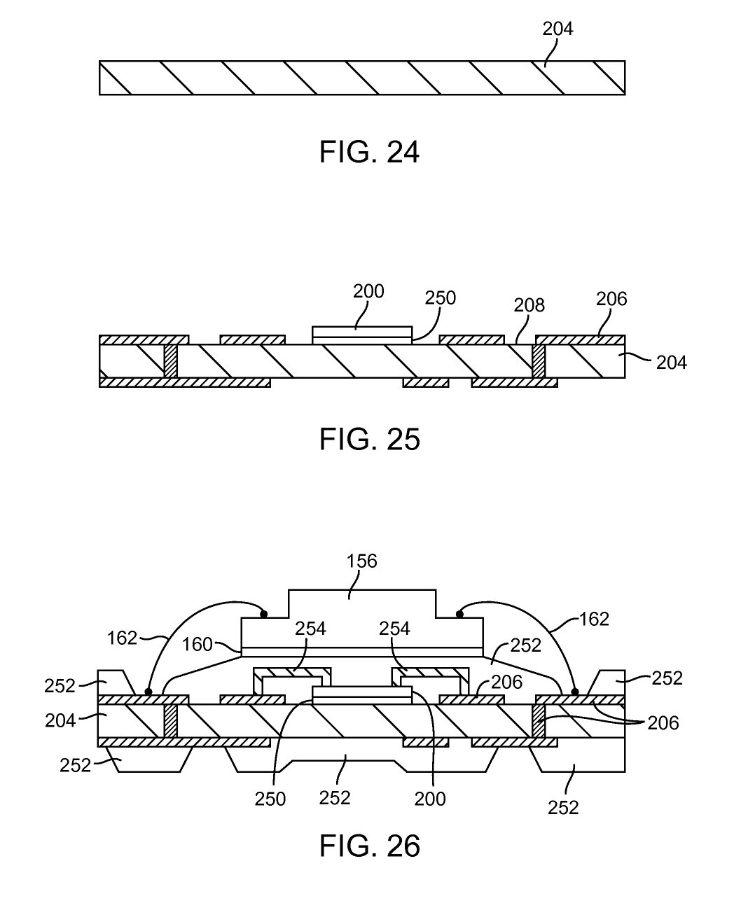

If desired, a redistribution layer may be formed on the upper surface of flexible printed circuit 58. The redistribution layer may contain metal traces that are used in forming signal paths coupled to semiconductor strain gauge 200. This type of approach is shown in FIGS. 24, 25, and 26.

Initially, a flexible printed circuit substrate may be provided, as shown in FIG. 24. Substrate 204 of FIG. 24 may be, for example, a flexible polyimide substrate or other flexible polymer layer. As shown in FIG. 25, the upper and/or lower surfaces of substrate 204 may be provided with patterned metal traces 206. Semiconductor strain gauge 200 may be mounted on upper surface 208 of substrate 204 using adhesive layer 250.

After forming the structures of FIG. 25 (which may, if desired, include multiple flexible printed circuit substrate layers and additional layer of adhesive and metal traces), additional polymer may be applied to the upper and lower surfaces of substrate 204 and fingerprint sensor 156 may be mounted to flexible printed circuit 58 using adhesive 160, as shown in FIG. 26. The additional polymer may be used in forming upper and lower dielectric cover layers for flexible printed circuit 58. Openings in the dielectric material of the cover layers may permit wire bonds 162 to form contacts between fingerprint sensor 156 and metal traces 206. Dielectric 252 of FIG. 26 (e.g., polyimide or other polymer) may include one or more laminated layers, one or more photoimageable layers, or other layers of dielectric material. As shown in FIG. 26, metal traces 254 in dielectric 252 may be used to form a redistribution layer on the upper surface of substrate 204. Metal traces 254 may be formed from the same types of metals as traces 206 (e.g., copper, etc.) or may be formed using different metals (as examples). Traces 254 and traces 206 may be interconnected.

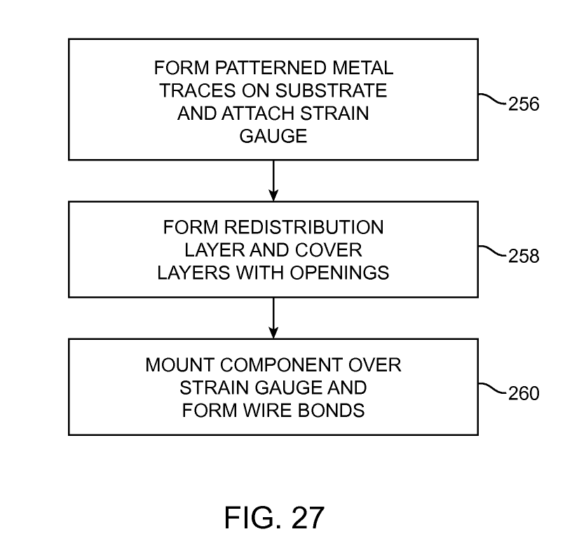

Illustrative steps involved in forming flexible printed circuit 58 of FIG. 26 are shown in FIG. 27.

At step 256, a flexible printed circuit structure is formed that includes patterned metal traces 206 on a flexible printed circuit substrate such as flexible printed circuit substrate 202. Semiconductor strain gauge 200 may be mounted on the upper surface of the flexible printed circuit substrate using a layer of adhesive. The flexible printed circuit substrate may, if desired, be attached to one or more additional substrate layers, one or more adhesive layers, and/or one or more metal layers.

At step 258, additional material may be added to the flexible printed circuit substrate. For example, upper and lower polyimide cover layers may be added. The additional material may include one or more additional polyimide layers, one or more adhesive layers, and/or one or more metal layers. A redistribution layer may be formed in the additional material. The metal traces of the redistribution layer may form part of the metal traces forming interconnects in flexible printed circuit 58 and may be coupled to semiconductor strain gauge 200. As shown in FIG. 26, the redistribution layer traces may overlap semiconductor strain gauge 200.

At step 260, fingerprint sensor 156 or other electrical circuitry may be mounted over semiconductor strain gauge 200 and the overlapping redistribution layer. Fingerprint sensor 156 may be coupled to the metal traces of flexible printed circuit 58 using wire bonds or other conductive paths. Flexible printed circuit 58 may be mounted in device 10 (e.g., by attaching fingerprint sensor 156 to display cover layer 52.

The foregoing is merely illustrative and various modifications can be made by those skilled in the art without departing from the scope and spirit of the described embodiments. The foregoing embodiments may be implemented individually or in any combination.

What is claimed is:

1. A flexible printed circuit, comprising:
a flexible printed circuit substrate; and
a semiconductor strain gauge formed in an opening in the flexible printed circuit substrate;
encapsulant that fills the opening;
a via that passes through the encapsulant to the semiconductor strain gauge; and
a metal trace that contacts the via.

2. The flexible printed circuit defined in claim 1 wherein the encapsulant has a surface and wherein the metal trace lies at least partly on the surface.

3. The flexible printed circuit defined in claim 2 wherein the flexible printed circuit substrate comprises a polyimide substrate layer.

4. The flexible printed circuit defined in claim 2 wherein the semiconductor strain gauge comprises a silicon strain gauge resistor.

5. The flexible printed circuit defined in claim 4 wherein the metal trace comprises copper.

6. The flexible printed circuit defined in claim 4 further comprising a polymer cover layer having an opening, wherein a portion of the metal trace is exposed in the opening.

7. The flexible printed circuit defined in claim 6 further comprising:
a fingerprint sensor mounted over the semiconductor strain gauge; and
a wire bond coupled between the fingerprint sensor and the metal trace.

8. The flexible printed circuit defined in claim 1 further comprising a layer of polyimide that covers the opening.

9. A flexible printed circuit, comprising:
a flexible printed circuit substrate having an opening;
a semiconductor strain gauge mounted in the opening;
metal traces on the flexible printed circuit substrate; and
wire bonds coupled between the semiconductor strain gauge and the metal traces.

10. The flexible printed circuit defined in claim 9 further comprising a component mounted across the opening.

11. The flexible printed circuit defined in claim 10 further comprising a layer of adhesive that attaches the semiconductor strain gauge to the component.

12. The flexible printed circuit defined in claim 10 wherein the component comprises a fingerprint sensor.

13. The flexible printed circuit defined in claim 9 wherein the opening passes through the flexible printed circuit substrate.

14. The flexible printed circuit defined in claim 13 wherein the flexible printed circuit substrate comprises a polyimide layer and wherein the semiconductor strain gauge comprises a strain-sensing silicon strain gauge resistor.

15. A flexible printed circuit, comprising:
a flexible printed circuit polymer substrate layer having opposing first and second surfaces;
a semiconductor strain gauge mounted on the first surface;
dielectric on the first surface that covers the semiconductor strain gauge; and
a metal trace in the dielectric, wherein the metal trace in the dielectric overlaps the semiconductor strain gauge and is coupled to the semiconductor strain gauge.

16. The flexible printed circuit defined in claim 15 further comprising a metal trace on the first surface.

17. The flexible printed circuit defined in claim 16, wherein the dielectric comprises polyimide and wherein the polyimide has an opening that exposes a portion of the metal trace on the first surface.

18. The flexible printed circuit defined in claim 17 further comprising an electrical component attached to the dielectric.

19. The flexible printed circuit defined in claim 18 further comprising a wire bond coupled between the electrical component and the exposed portion of the metal trace on the first surface.

20. The flexible printed circuit defined in claim 19 wherein the electrical component comprises a fingerprint sensor that overlaps the metal trace in the dielectric.
